(19) United States
(12) Patent Application Publication
(10) Pub. No.: US 2007/0196993 A1
(43) Pub. Date: Aug. 23, 2007

(54) Semiconductor element

(76) Inventors: Shinichi Iwakami, Niiza-shi (JP); Osamu Machida, Niiza-shi (JP); Masataka Yanagihara, Niiza-shi (JP)

Correspondence Address: HOWARD & HOWARD ATTORNEYS, P.C., THE PINEHURST OFFICE CENTER, SUITE #101, 39400 WOODWARD AVENUE, BLOOMFIELD HILLS, MI, 48304-5151, US

(21) Appl. No.: 11/701,327

(22) Filed: Feb. 1, 2007

(30) Foreign Application Priority Data
Feb. 2, 2006 (JP) 2006-025615

(51) Int. Cl. H01L 21/8222

(52) U.S. Cl. 438/328

(57) ABSTRACT

A Schottky diode includes a substrate, a channel layer formed on the substrate and made of nitride-based compound semiconductor, an anode electrode and a cathode electrode which constitute an end portion of the current path of the semiconductor element, and a dummy electrode electrically connected to the substrate. The anode electrode is formed to have a Schottky barrier junction with the channel layer. The cathode layer is formed to have a low-resistance contact with the channel layer.

### BACKGROUND OF THE INVENTION

1. Field of the Invention

The present invention relates to a semiconductor element, and particularly relates to a semiconductor element using a nitride-based compound semiconductor.

2. Description of the Related Art

A nitride-based compound semiconductor such as gallium nitride (GaN) attracts attention as a semiconductor material having favorable properties in terms of high temperature, high power, and high frequency. For example, a nitride-based compound semiconductor has a wider gap than that of a silicon semiconductor, and is therefore suitable as a material of a semiconductor element, which is required to be stable in high-temperature operations. Further, since a nitride-based compound semiconductor can have a high electron mobility if it has a heterostructure made of AlGaN, GaN, or the like, it is suitable as a material of a semiconductor element, which is required to have a high switching speed or to deal with a large current. Further, since the breakdown electric field (the strength of the insulation breakdown field) of a nitride-based compound semiconductor is high, a nitride-based compound semiconductor is suitable as a material of a semiconductor element, which is required to operate at a high voltage.

A nitride-based compound semiconductor has deep levels (traps) of a large quantity exist in its bulk crystal or in its semiconductor surface. Therefore, while a semiconductor element is operating, a so-called current collapse phenomenon in a semiconductor substrate occurs in a semiconductor substrate, which comprises a nitride-based compound semiconductor, in which phenomenon carriers are caught into the traps in the semiconductor substrate and thereby the current to be output thereafter is reduced.

To solve such a problem, a structure formed of a substrate serving as a base, and a channel layer formed thereupon, between which a buried p-type layer is provided, is known. As disclosed in, for example, Unexamined Japanese Patent Application KOKAI Publication No. 2000-286428, a field effect transistor comprises a buried p-type layer provided under a channel layer, and an external n-type electrode provided above the buried p-type layer and electrically insulated from the channel layer. The buried p-type layer and the external n-type electrode constitute a diode, and the external n-type electrode is connected to a second gate electrode on the channel layer. Therefore, since carriers that have reached the buried p-type layer are supplied to the second gate electrode through the external n-type electrode, occurrence of a current collapse phenomenon in the semiconductor substrate can be favorably prevented.

### SUMMARY OF THE INVENTION

However, a semiconductor element has many traps for trapping carriers generated also in the surface of the semiconductor substrate (in the surface of the channel layer), not only in the semiconductor substrate. When a reverse bias is applied to such a semiconductor element, carriers are trapped by the traps that exist in the surface of the semiconductor substrate. Accordingly, a so-called current collapse phenomenon in the surface of a semiconductor substrate will occur, in which phenomenon a current to be output when a forward bias is thereafter applied to the semiconductor element will reduce.

The present invention was made in view of the above-described problem, and an object of the present invention is to provide a semiconductor element which can favorably prevent a current collapse phenomenon.

To achieve the above object, a semiconductor element according to a first aspect of the present invention comprises:

a substrate;

a channel layer formed on one principal surface of said substrate, and made of nitride-based compound semiconductor;

first and second electrodes formed on said channel layer and constituting an end portion of a current path of said semiconductor element; and

a dummy electrode formed on said channel layer and electrically connected to said substrate,

wherein said first electrode is formed to have a Schottky barrier junction with said channel layer, and

said second electrode is formed to have a low-resistance contact with said channel layer.

A semiconductor element according to a second aspect of the present invention comprises:

a substrate;

a channel layer formed on one principal surface of said substrate and made of nitride-based compound semiconductor;

a first electrode formed on said channel layer, for controlling a current path of said semiconductor element;

a second electrode formed on said channel layer, for functioning as a drain electrode;

a third electrode formed on said channel layer, for functioning as a source electrode; and

a dummy electrode formed on said channel layer and electrically connected to said substrate.

### BRIEF DESCRIPTION OF THE DRAWINGS

These objects and other objects and advantages of the present invention will become more apparent upon reading of the following detailed description and the accompanying drawings in which:

FIG. 1 is a cross sectional diagram showing a structure of a Schottky diode as the first embodiment of the present invention;

FIG. 2 is a plan view of the Schottky diode of FIG. 1, as seen from the top;

FIG. 3 is a cross sectional diagram showing a state that a reverse bias is applied to the Schottky diode of FIG. 1;

FIG. 4 is a cross sectional diagram of the Schottky diode of FIG. 1, which is provided with a filter;

FIG. 5 is a cross sectional diagram showing a structure of a MESFET as the second embodiment of the present invention;

FIG. 6 is a cross sectional diagram showing a state that a reverse bias is applied to the MESFET of FIG. 5;

FIG. 7 is a diagram showing a modified example of the Schottky diode of the first embodiment; and

FIG. 8 is a diagram showing a modified example of the Schottky diode of the first embodiment.

### DETAILED DESCRIPTION OF THE PREFERRED EMBODIMENTS

### First Embodiment

A semiconductor element according to the first embodiment of the present invention will be explained below. In the present embodiment, an explanation will be given to an example in which a Schottky diode is used as a semiconductor element.

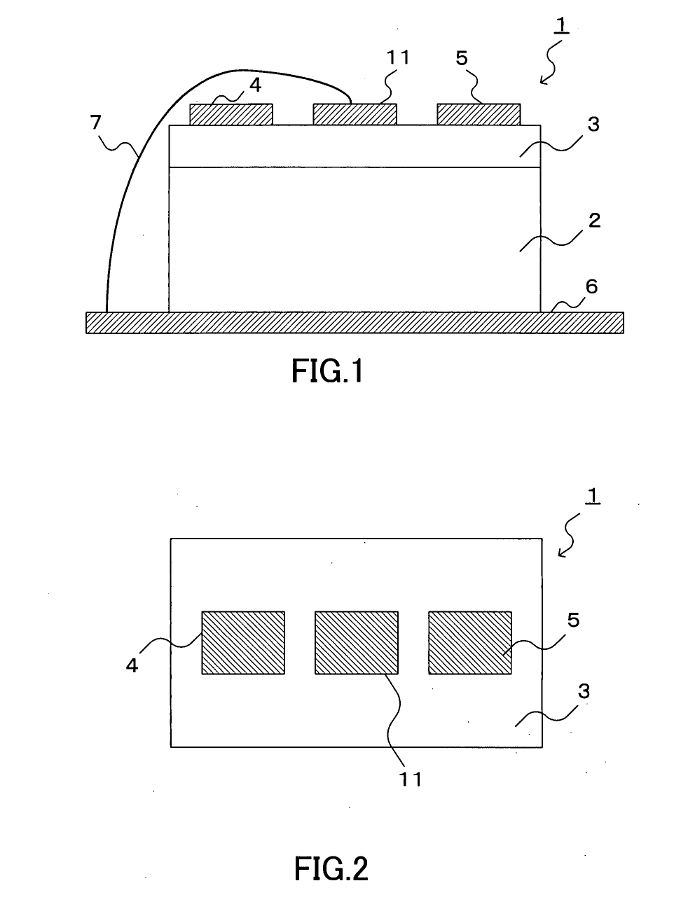

FIG. 1 is a cross sectional diagram showing the structure of a Schottky diode according to the first embodiment. FIG. 2 is a diagram of the Schottky diode of the first embodiment as seen from the top, showing an example of the arrangement of each electrode of the Schottky diode. As shown in FIG. 1, the Schottky diode 1 comprises a substrate 2, a channel layer 3, an anode electrode 4 as a first electrode, a cathode electrode 5 as a second electrode, and a dummy electrode 11.

For example, a silicon monocrystal substrate is used as the substrate 2. The channel layer 3, the anode electrode 4, etc. are formed on one principal surface (the upper side shown in FIG. 1) of the substrate 2. A frame 6 for supporting the substrate 2 is connected to the other principal surface (the lower side shown in FIG. 1) of the substrate 2. As will be described later, the frame 6 is formed of a conductive member.

The channel layer 3 is formed on one principal surface, for example, the upper surface, of the substrate 2. The channel layer 3 is made of, for example, nitride-based compound semiconductor. Nitride-based compound semiconductor includes, for example, gallium nitride (GaN), aluminum gallium nitride (AlGaN), etc. The channel layer 3 is formed on the substrate 2, by depositing GaN by, for example, metalorganic chemical vapor deposition (MOCVD). Though not illustrated, a nucleation layer (buffer layer) made of GaN or the like is sandwiched between the channel layer 3 and the substrate 2.

The anode layer 4 and the cathode layer 5 are formed on predetermined regions on the channel layer 3 (on the principal surface of the Schottky diode 1). The anode electrode 4 and the cathode electrode 5 are main electrodes through which a principal current (output current) of the semiconductor element flows, and constitute an end portion of the current path of the semiconductor element.

The anode electrode 4 is formed to have, for example, a Schottky barrier junction with the channel layer 3. According to the present embodiment, the anode electrode 4 is formed of a nickel (Ni) film or a platinum (Pt) film, and a gold (Au) film formed on the Ni film or the Pt film. The anode electrode 4 is formed on the channel layer 3, by forming a Ni film (or a Pt film) and an Au film on the channel layer 3 by, for example, sputtering or the like, and patterning them into a predetermined shape by dry etching or the like.

The cathode electrode 5 is formed to have, for example, a low-resistance contact (Ohmic contact) with the channel layer 3. According to the present embodiment, the cathode electrode 5 is formed on the channel layer 3, by forming a titanium (Ti) film and an aluminum (Al) film on the channel layer 3 by, for example, sputtering or the like, and patterning them into a predetermined shape by dry etching or the like.

The dummy electrode 11 is formed on a predetermined region on the channel layer 3 (one principal surface of the Schottky diode 1) between the anode electrode 4 and cathode electrode 5 on the channel layer 3. The dummy electrode 11 is an electrode through which no principal current of the semiconductor element flows. Therefore, if the semiconductor element is, for example, a switching element, the dummy electrode 11 does not have a function as a control element for switching ON/OFF the output of the semiconductor element.

The dummy electrode 11 is formed to have, for example, a Schottky barrier junction with the channel layer 3. According to the present embodiment, the dummy electrode 11 is formed on the channel layer 3 by patterning a material into a predetermined shape by, for example, sputtering or the like. Therefore, the dummy electrode 11 can be formed at the same time as the anode electrode 4.

The dummy electrode 11 is electrically connected to the substrate 2. According to the present embodiment, the dummy electrode 11 is electrically connected to the substrate 2, by being connected to the frame 6 by a wire 7.

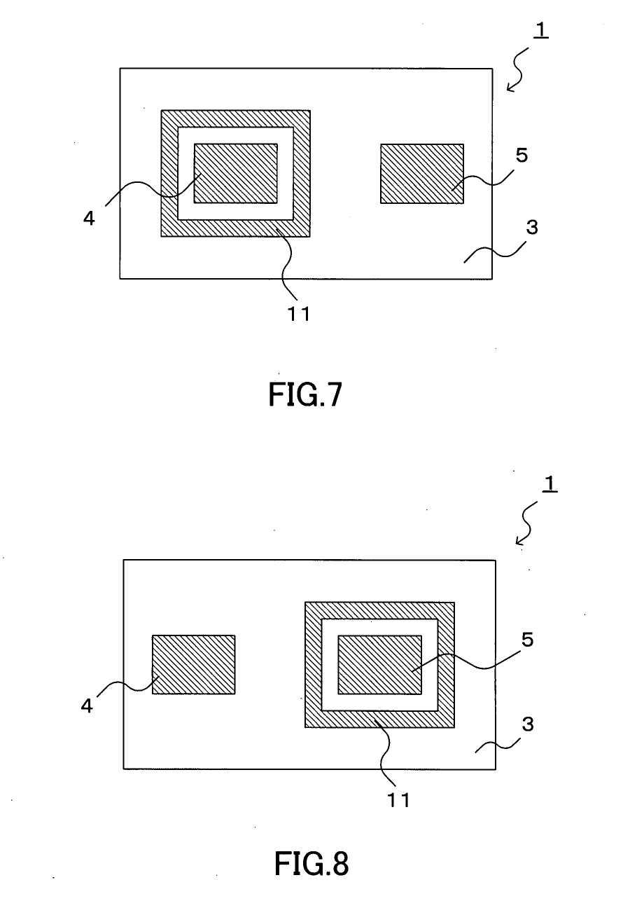

It is preferred that the dummy electrode 11 be formed apart from the anode electrode 4 and cathode electrode 5, and be formed to surround the anode electrode 4 as shown in FIG. 7 and/or to surround the cathode electrode 5 as shown in FIG. 8. Note that it is preferred that the dummy electrode 11 be formed to surround the anode electrode 4.

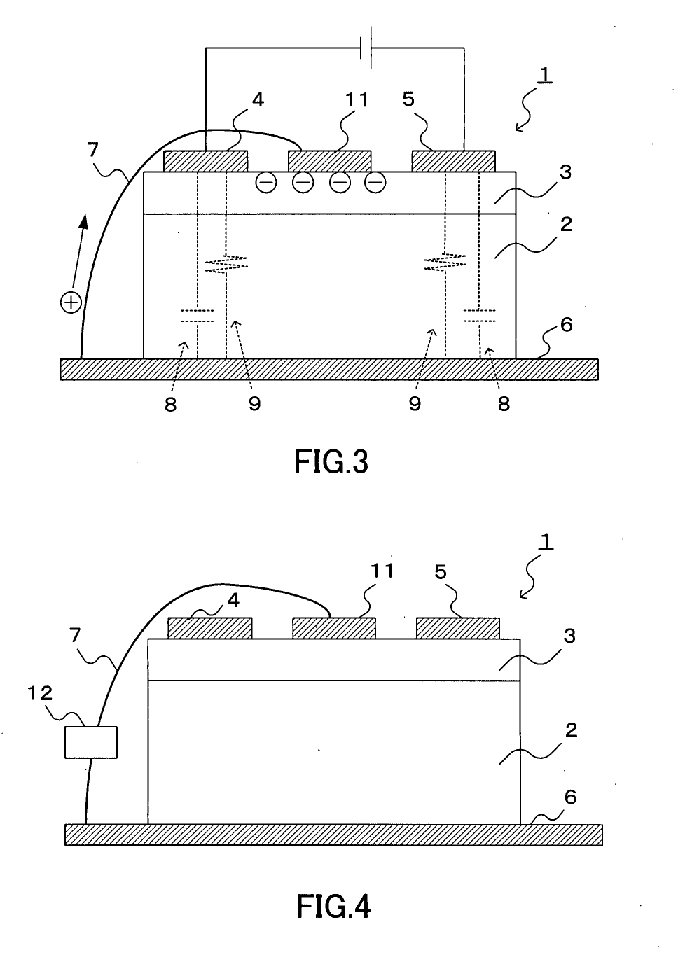

Workings and effects of the Schottky diode 1 having the above-described structure will be explained. FIG. 3 shows the Schottky diode 1, to which a reverse bias (in which the anode electrode 4 will have a lower potential than that of the cathode electrode 5) is being applied.

When a reverse bias is applied to a conventional Schottky diode, electrons as carriers are trapped into traps in the surface of the channel layer and stored (injected) therein. Therefore, when, after this, a forward bias is applied to the conventional Schottky diode, a current collapse phenomenon will occur.

In the Schottky diode 1 of the present embodiment, since the frame 6 is formed on the lower surface of the substrate 2 and the dummy electrode 11 is connected to the frame 6 by the wire 7, the lower surface of the substrate 2 and the dummy electrode 11 formed on the surface of the channel layer 3 have electrically the same potential as each other.

Here, when a reverse bias is applied to the Schottky diode 1, a parasitic capacitance 8 and a parasitic resistance 9 are generated between the anode electrode 4 and the frame 6, and between the cathode electrode 5 and the frame 6, as shown in FIG. 3.

In FIG. 3, the parasitic capacitance 8 and the parasitic resistance 9 are illustrated as being connected, at their one end, to the frame 6. However, in an actual structure, the parasitic capacitance 8 and the parasitic resistance 9 may not have their one end connected to the frame 6. For example, in a case where a conductive substrate is used as the substrate 2, since the substrate 2 is electrically conductive, it is reasonable to consider that the parasitic capacitance 8 and the parasitic resistance 9 have their one end connected to the interface between the substrate 2 and the channel layer 3. Accordingly, it is only necessary that one end of the wire 7 is connected to the dummy electrode 11 and the other end of the wire 7 is electrically connected to the interface between the substrate 2 and the channel layer 3, so the frame 6 may be omitted. For example, one end of the wire 7 may be connected to the dummy electrode 11, and the other end of the wire 7 may be connected to an exposed portion of the substrate 2 (or the nucleation layer) on one principal surface of the substrate 2 (or the nucleation layer), on which the channel layer 3 is not formed.

When a reverse bias is applied across the anode electrode 4 and the cathode electrode 5, the potential of the frame 6 determines the potential distribution across the anode electrode 4 and the cathode electrode 5, direct-current-wise (stationarily) or alternating-current-wise (transiently), depending on the parasitic capacitance 8 and the parasitic resistance 9. That is, depending on the parasitic capacitance 8 and parasitic resistance 9 generated, the potential of the frame 6 increases with respect to the potential of the anode electrode 4, and the potential of the dummy electrode 11 electrically connected to the frame 6 by the wire 7 also increases accordingly. As shown in FIG. 3, since many electrons exist near the dummy electrode 11 while being trapped in the traps present in the surface of the channel layer 3, the potential at the surface of the channel layer 3 is lowered by these electrons. Accordingly, holes (+charges) migrate from the lower surface side of the substrate 2 to the dummy electrode 11 and cancel the electrons existing in the surface of the channel layer 3. It is possible to consider oppositely that the electrons trapped in the surface of the channel layer 3 are drawn by the potential of the dummy electrode 11 (the frame 6) to be extinct from the traps in the surface of the channel layer 3. Therefore, it is possible to reduce the factor to cause a current collapse phenomenon that a principal current will be reduced when a forward bias is applied after the reverse bias is applied. As a result, it is possible to prevent occurrence of a current collapse phenomenon.

As explained above, according to the present embodiment, since the dummy electrode 11 is electrically connected to the frame 6 formed on the lower surface of the substrate 2, it is possible to prevent a current collapse phenomenon from occurring due to electrons being stored in the traps in the surface of the channel layer 3. Further, since it is only needed that the dummy electrode 11 is electrically connected to the frame 6, the withstand voltage across the anode electrode 4 and the cathode electrode 5, and across the frame 6 and the anode electrode 4 or the cathode electrode 5 needs not be lowered in order to favorably prevent a current collapse phenomenon. Furthermore, it is possible to easily prevent a current collapse phenomenon, with almost no changes in the conventional design.

### Second Embodiment

A semiconductor element according to a second embodiment of the present invention will be explained. In the present embodiment, the present invention will be explained in an example where a transistor (MESFET: Metal Semiconductor Field Effect Transistor) is used as a semiconductor element.

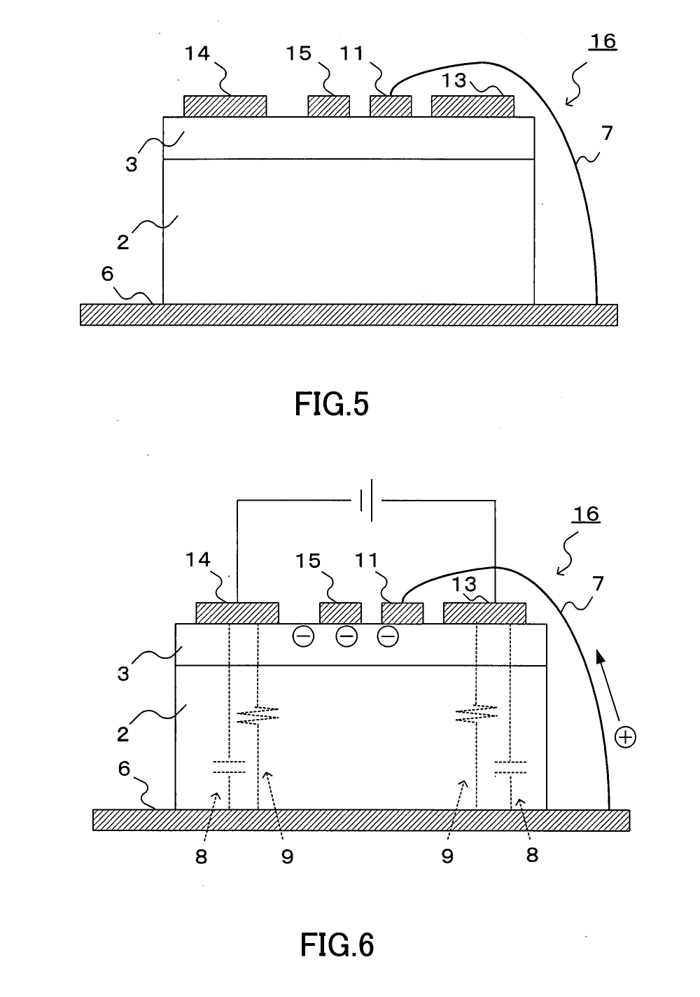

FIG. 5 is a cross sectional diagram showing the structure of a MESFET 16 according to the present embodiment. As shown in FIG. 5, the MESFET 16 comprises a substrate 2, a channel layer 3, a dummy electrode 11, a gate electrode 15 as a first electrode, a drain electrode 13 as a second electrode, and a source electrode 14 as a third electrode. In the second embodiment of the present invention, components that are the same as components of the first embodiment will be denoted by the same reference numerals and explanation for such components will be omitted.

The drain electrode 13 and the source electrode 14 are formed on predetermined regions of the channel layer 3 (on a principal surface of the MESFET 16). The drain electrode 13 and the source electrode 14 are main electrodes through which a principal current (output current) of the semiconductor element flows, and constitute an end portion of the current path of the semiconductor element.

The drain electrode 13 and the source electrode 14 are formed to have, for example, a low-resistance contact (Ohmic contact) with the channel layer 3. According to the present embodiment, the drain electrode 13 and the source electrode 14 are formed on the channel layer 3, by forming a Ti film and an Al film on the channel layer 3 by, for example, sputtering or the like, and patterning them into a predetermined shape by dry etching or the like.

The gate electrode 15 is formed on a predetermined region of the channel layer 3 (on a principal surface of the MESFET 16). The gate electrode 15 is arranged between the drain electrode 13 and the source electrode 14 so as to be apart from both of them. The gate electrode 15 is an electrode for controlling the principal current of the semiconductor element. Therefore, in a case where the semiconductor element is a switching element, the gate electrode 15 has a function as a control element for switching ON/OFF the output of the semiconductor element. The gate electrode 15 is formed to have, for example, a Schottky barrier junction with the channel layer 3. According to the present embodiment, the gate electrode 15 is made of a nickel (Ni) film or a platinum (Pt) film, and a gold (Au) film formed on the Ni film or the Pt film. The gate electrode 15 is formed on the channel layer 3, by forming a Ni film (or a Pt film) and an Au film on the channel layer 3 by, for example, sputtering or the like, and patterning them into a predetermined shape by, for example, sputtering or the like.

The dummy electrode 11 is formed on a predetermined region of the channel layer 3 (on a principal surface of the MESFET 16) between the drain electrode 13 and the gate electrode 15 on the channel layer 3. The dummy electrode 11 is an electrode through which no principal current of the semiconductor element flows. Therefore, in a case where the semiconductor element is, for example, a switching element, the dummy electrode 11 does not have a function as a control element for switching ON/OFF the output of the semiconductor element.

The dummy electrode 11 is formed to have, for example, a Schottky barrier junction with the channel layer 3. According to the present embodiment, the dummy electrode 11 is formed on the channel layer 3, by patterning a material into a predetermined shape by, for example, sputtering or the like. Therefore, the dummy electrode 11 can be formed at the same time as the gate electrode 15.

The dummy electrode 11 is electrically connected to the substrate 2. According to the present embodiment, the dummy electrode 11 is electrically connected to the substrate 2, by being connected to a frame 6 by a wire 7.

Since the dummy electrode 11 is intended to prevent a reduction in the principal current due to a current collapse phenomenon, it is formed between the drain electrode 13 and the source electrode 14, which are the main electrodes. Here, it is preferred that the dummy electrode 11 be formed between the gate electrode 15 and the drain electrode 13. This is because electrons, which are trapped in the traps in the surface of the channel layer 3, are present more concentratively between the drain electrode 13 and the gate electrode 15 than between the source electrode 14 and the gate electrode 15. Further, it is preferred that the dummy electrode 11 be formed to surround at least any one of the gate electrode 15 and the drain electrode 13, likewise the first embodiment. This is because, if particularly, the dummy electrode 11 surrounds at least any one of the gate electrode 15 and the drain electrode 13, a current collapse phenomenon can more favorably be reduced.

Workings and effects of the MESFET 16 having the above-described structure will be explained. FIG. 6 shows the MESFET 16, to which a reverse bias (in which the gate electrode 15 is switched OFF and the drain electrode 13 has a higher potential than that of the source electrode 14) is being applied.

When a reverse bias is applied to the MESFET 16, electrons are trapped into the traps in the surface of the channel layer 3 and stored (injected) therein, likewise in the first embodiment (FIG. 3).

In a conventional MESFET 16, the electrons stored in the surface of the channel layer 3 cause a current collapse phenomenon.

According to the present embodiment, since the frame 6 is formed on the lower surface of the substrate 2 and the dummy electrode 11 is connected to the frame 6 by the wire 7, the lower surface of the substrate 2 and the dummy electrode 11 formed on the surface of the channel layer 3 have electrically the same potential as each other.

Here, when a reverse bias is applied to the MESFET 16, a parasitic capacitance 8 and a parasitic resistance 9 are generated between the drain electrode 13 and the frame 6, and between the source electrode 14 and the frame 6, as shown in FIG. 6.

In FIG. 6, the parasitic capacitance 8 and the parasitic resistance 9 have their one end connected to the frame 6. However, the parasitic capacitance 8 and the parasitic resistance 9 may not have their one end connected to the frame 6. For example, in a case where a conductive substrate is used as the substrate 2, since the substrate 2 has electric conductivity, it is reasonable to consider that the parasitic capacitance 8 and the parasitic resistance 9 have their one end connected to the interface between the substrate 2 and the channel layer 3. Accordingly, it is only necessary that one end of the wire 7 is connected to the dummy electrode 11 and the other end of the wire 7 is electrically connected to the interface between the substrate 2 and the channel layer 3. Therefore, the frame 6 may be omitted. Further, it is also possible that one end of the wire 7 is connected to the dummy electrode 11, and the frame 6 is formed on an exposed portion of the substrate 2 (or a nucleation layer) on one principal surface of the substrate 2 (or the nucleation layer) where the channel layer 3 is not formed, so that the frame 6 and the other end of the wire 7 may be connected to each other.

When a reverse bias is applied across the drain electrode 13 and the source electrode 14, the voltage is distributed direct-current-wise (stationarily) or alternating-current-wise (transiently). That is, depending on the parasitic capacitance 8 and the parasitic resistance 9 generated, the potential of the frame 6 increases with respect to the potential of the source electrode 14, and the potential of the dummy electrode 11 also increases accordingly. Since the potential of the frame 6 increases, the potential of the dummy electrode 11, which is electrically connected to the frame 6 by the wire 7, also increases in line with this. Since many electrons exist near the dummy electrode 11 while being trapped in the traps present in the surface of the channel layer 3 as shown in FIG. 6, these electrons lower the potential at the surface of the channel layer 3. Accordingly, holes (+charges) migrate from the lower surface side of the substrate 2 to the dummy electrode 11 and cancel the electrons preset in the surface of the channel layer 3. It is possible to oppositely consider that the electrons trapped in the surface of the channel layer 3 are drawn by the potential of the dummy electrode 11 (frame 6) to be extinct from the traps in the surface of the channel layer 3. Therefore, it is possible to reduce a factor to cause a current collapse phenomenon that the principal current reduces when a forward bias is applied afterwards. As a result, it is possible to prevent occurrence of a current collapse phenomenon.

As explained above, according to the preset embodiment, since the dummy electrode 11 is electrically connected to the frame 6 formed on the lower surface of the substrate 2, it is possible to prevent a current collapse phenomenon from occurring due to electrons being stored in the traps in the surface of the channel layer 3. Further, since it is only necessary that the dummy electrode 11 is connected to the frame 6, it is possible to favorably prevent a current collapse phenomenon, with no need to lower the withstand voltage across the drain electrode 13 and the source electrode 14, and across the drain electrode 13 or the source electrode 14 and the frame 6. Furthermore, it is possible to easily prevent a current collapse phenomenon, with almost no changes in a conventional design.

The present invention is not limited to the above-described embodiments, but may be modified and applied in various manners. Other embodiments that can be applied to the present invention will be explained below.

For example, as shown in FIG. 4, a noise filter 12 comprising a coil, a resistor, a capacitor, etc. may be formed between the dummy electrode 11 of the Schottky diode 1 and the frame 6, i.e., on the wire 7. In this case, it is possible to prevent or decrease reduction in the effect of preventing a current collapse phenomenon, which might be caused if a noise generated in the path from the ground to the dummy electrode 11 enters the channel layer 3 through the dummy electrode 11. As the noise filter, a filter for reducing a low-frequency noise, which comprises, for example, a resistor and a capacitor, may be used. Further, a noise filter 12 may be provided on the wire 7 of the MESFET 16 shown in FIG. 5.

In the above-described embodiments, the present invention has been explained in the examples where the dummy electrode 11 is connected to the frame 6 by the wire 7. However, it is only necessary that the dummy electrode 11 is electrically connected to the substrate 2. Therefore, the connection between the dummy electrode 11 and the substrate 2 may not necessarily be by an external wire.

In the above-described embodiments, the present invention has been explained in the examples where the channel layer 3 is made of nitride-based compound semiconductor. However, the channel layer 3 is not limited to a single layer made of nitride-based compound semiconductor, but may be formed of a heterojunction having different energy bands. For example, the channel layer may have a dual-layer structure, which includes a first Al_{X}Ga_{Y}M_{1-X-Y}N (0≦X≦1, 0≦Y≦1, 0<1−X−Y≦1) layer, and a second Al_{α}Ga_{β}M_{1-α-β}N (0≦α≦1, 0≦β≦1, 0<1−α−β≦1) layer, which is formed on the first Al_{X}Ga_{Y}M_{1-X-Y}N layer and has a different composition from that of the first Al_{X}Ga_{Y}M_{1-X-Y}N layer. Here, M is any one of indium (In) and boron (B).

Further, a nucleation layer (buffer layer) may be formed between the channel layer 3 and the substrate 2, in order to pass on the crystal orientation of the substrate 2 favorably to the channel layer 3. If a nucleation layer is formed, the channel layer 3 to be provided on the upper surface of the nucleation layer can be formed favorably with its orientation uniformed. Therefore, the electric properties of the semiconductor element can be improved. As a nucleation layer, Al_{K}Ga_{1-K}N (0<K≦1) and GaN may be alternately stacked, or a well-known nucleation layer such as a low-temperature buffer layer comprising a single layer made of an Al_{K}Ga_{1-K}N layer or a GaN layer may be provided. The buffer layer is less likely to be transformed into an amorphous state, if more layers are stacked alternately, than if a single layer is formed. This reduced likeliness reduces crystal deficiencies in the channel layer 3 stacked on the nucleation layer, and makes it harder for electrons to be trapped into the surface of the channel layer 3. Accordingly, it is possible to further prevent a current collapse phenomenon in the surface of the channel layer 3.

Further, in the above-described embodiments, the present invention has been explained in the examples where the substrate 2 is made of silicon monocrystal. However, the substrate 2 may be formed of an insulating substrate made of, for example, sapphire (Al₂O₃), silicon carbide (SiC), or the like, or a conductive substrate made of another material than GaN substrate and silicon.

In the above-described embodiment, the explanation has been given on a MESFET as an example. However, the present invention may be applied to a HEMT (High Electron Mobility Transistor).

Further, the dummy electrode 11 may be formed not only to have a Schottky barrier junction but also a MIS (Metal Insulator Semiconductor) structure with the channel layer 3.

Furthermore, the gate electrode 15 is not limited to an electrode which has a Schottky barrier junction with the channel layer 3, but may have a MIS structure with the channel layer 3.

Various embodiments and changes may be made thereunto without departing from the broad spirit and scope of the invention. The above-described embodiments are intended to illustrate the present invention, not to limit the scope of the present invention. The scope of the present invention is shown by the attached claims rather than the embodiments. Various modifications made within the meaning of an equivalent of the claims of the invention and within the claims are to be regarded to be in the scope of the present invention.

This application is based on Japanese Patent Application No. 2006-025615 filed on Feb. 2, 2006 and including specification, claims, drawings and summary. The disclosure of the above Japanese Patent Application is incorporated herein by reference in its entirety.

What is claimed is:

1. A semiconductor element, comprising:
a substrate;
a channel layer formed on one principal surface of said substrate, and made of nitride-based compound semiconductor;
first and second electrodes formed on said channel layer and constituting an end portion of a current path of said semiconductor element; and
a dummy electrode formed on said channel layer and electrically connected to said substrate,
wherein said first electrode is formed to have a Schottky barrier junction with said channel layer, and
said second electrode is formed to have a low-resistance contact with said channel layer.

2. The semiconductor element according to claim 1, wherein said dummy electrode is formed to have a Schottky barrier junction with said channel layer or to have a MIS structure with said channel layer.

3. The semiconductor element according to claim 1, wherein said dummy electrode is formed between said first electrode and said second electrode.

4. The semiconductor element according to claim 1, wherein said dummy electrode is formed to surround either one of said first electrode and said second electrode, when it is seen from above the one principal surface of said substrate.

5. The semiconductor element according to claim 1, wherein said substrate is an insulating substrate.

6. The semiconductor element according to claim 1, further comprising
a frame having conductivity, formed on the other principal surface of said substrate or on an exposed portion of the one principal surface of said substrate on which said channel layer is not formed,
wherein said frame and said dummy electrode are electrically connected to each other.

7. A semiconductor element, comprising:
a substrate;
a channel layer formed on one principal surface of said substrate and made of nitride-based compound semiconductor;
a first electrode formed on said channel layer, for controlling a current path of said semiconductor element;
a second electrode formed on said channel layer, for functioning as a drain electrode;
a third electrode formed on said channel layer, for functioning as a source electrode; and
a dummy electrode formed on said channel layer and electrically connected to said substrate.

8. The semiconductor element according to claim 7, wherein said first electrode is formed to have a Schottky barrier junction with said channel layer or to have a MIS structure with said channel layer, and said second electrode is formed to have a low-resistance contact with said channel layer.

9. The semiconductor element according to claim 7, wherein said dummy electrode is formed to have a Schottky barrier junction with said channel layer or to have a MIS structure with said channel layer.

10. The semiconductor element according to claim 7, wherein said dummy electrode is formed between said first electrode and said second electrode.

11. The semiconductor element according to claim 7, wherein said dummy electrode is formed to surround either one of said first electrode and said second electrode, when it is seen from above the one principal surface of said substrate.

12. The semiconductor element according to claim 7, wherein said substrate is an insulating substrate.

13. The semiconductor element according to claim 7, further comprising
a frame having conductivity, formed on the other principal surface of said substrate or on an exposed portion of the one principal surface of said substrate on which said channel layer is not formed,
wherein said frame and said dummy electrode are electrically connected to each other.
